(19) United States
(12) Patent Application Publication
(10) Pub. No.: US 2026/0333694 A1
(43) Pub. Date: Oct. 22, 2026

(54) MICROELECTRONIC DEVICES, AND RELATED METHODS AND MEMORY DEVICES

(71) Applicant: Micron Technology, Inc., Boise, ID (US)

(72) Inventors: Pengyuan Zheng, Boise, ID (US); Swapnil A. Lengade, Boise, ID (US); Haoyu Li, Boise, ID (US); Everett A. McTeer, Eagle, ID (US); Rita J. Klein, Boise, ID (US)

(21) Appl. No.: 19/632,791

(22) Filed: Mar. 30, 2026

Related U.S. Application Data
(60) Provisional application No. 63/790,495, filed on Apr. 17, 2025.

(51) Int. Cl. H10B 43/27; H10B 41/27

(52) U.S. Cl. CPC H10B 43/27; H10B 41/27

(57) ABSTRACT

A microelectronic device comprises a stack structure comprising tiers vertically stacked relative to one another. Each of the tiers comprises a composite conductive material and an insulative material vertically neighboring the composite conductive material. The composite conductive material comprises a conductive material and an amorphous alloy liner on each of an upper surface and a lower surface of the conductive material. The amorphous alloy liner comprises additional conductive material and dopant distributed within the additional conductive material. The dopant comprises or more of boron, carbon, and silicon.

### CROSS-REFERENCE TO RELATED APPLICATIONS

This application claims the benefit under 35 U.S.C. § 119(e) of U.S. Provisional Patent Application Ser. No. 63/790,495, filed Apr. 17, 2025, the disclosure of which is hereby incorporated herein in its entirety by this reference.

### TECHNICAL FIELD

The disclosure, in various embodiments, relates generally to microelectronic device design and fabrication. More specifically, the disclosure relates to microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. A continuing goal of the electronics industry has been to increase the memory density (e.g., the number of memory cells per memory die) of memory devices, such as non-volatile memory devices (e.g., NAND flash memory devices). One way of increasing memory density in non-volatile memory devices is to utilize vertical memory array (also referred to as a “three-dimensional memory array”) architectures. A conventional vertical memory array includes vertical memory strings extending through one or more stack structures having vertically alternating sequence of conductive structure and insulative structure. Each vertical memory string may include at least one select device coupled in series to a serial combination of vertically-stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

In the three-dimension memory devices (e.g., 3D NAND memory device), the conductive structures of the tiers of the stack structures may function as control gates for access lines (e.g., word lines) of the memory cells. The access lines are electrically connected with other conductive structures of the memory device so that the memory cells of the vertical memory strings can be selected for writing, reading, and erasing operation. One method of forming such an electrical connection includes forming so-called “staircase” structures at edges (e.g., horizontal ends) of the conductive structures of the stack structures of the memory device. The staircase structure includes individual “steps” defining contact regions upon which conductive contacts can be formed for electrical connection to the conductive structures such as the access line of the memory cells.

As vertical memory array technology has advanced, additional memory density has been provided by forming vertical memory arrays to include the stack structures comprising additional tiers of conductive structures and, hence, additional staircase structures and/or additional steps in individual staircase structures associated therewith. As the height of the stack structures increases to facilitate additional memory cells in the vertical memory arrays, the stack structures may be prone to bending, deflection, or toppling during various processing acts. For example, during replacement gate process, the stack structures may be subject to tier bending and/or tier deflection during or after portions of the tiers are removed and replaced with the conductive structure. Bending or deflection of the portions of the stack structures may reduce reliability of the vertical memory strings.

### BRIEF DESCRIPTION OF THE DRAWINGS

FIG. 1A through FIG. 13C are simplified, partial top-down views (FIGS. 1A, 2A, 3A, 4A and 13A) and simplified, partial cross-sectional views (FIGS. 1B, 1C, 2B, 2C, 3B, 3C, 4B, 4C, 5 through 12, 13B and 13C) illustrating different processing stages of a method of forming a microelectronic device, in accordance with embodiments of the disclosure;

FIG. 14 is a simplified, partial cutaway perspective view of a microelectronic device, in accordance with embodiments of the disclosure; and

FIG. 15 is a schematic block diagram illustrating an electronic system, in accordance with embodiments of the disclosure.

### DETAILED DESCRIPTION

The following description provides specific details, such as material types, material thicknesses, and processing conditions in order to provide a thorough description of embodiments of the disclosure. However, a person of ordinary skill in the art will understand that embodiments of the present disclosure may be practiced without employing these specific details. Indeed, the embodiments of the present disclosure may be practiced in conjunction with conventional fabrication techniques employed in the industry. In addition, the description provided herein does not form a complete process flow for forming a semiconductor device structure, and the semiconductor device structures described below do not form a complete semiconductor device. Only those process acts and structures necessary to understand the embodiments of the present disclosure are described in detail below. Additional acts to form the complete semiconductor device may be performed by conventional fabrication techniques.

Drawings presented herein are for illustrative purposes only and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. Furthermore, the drawings accompanying the application are for illustrative purposes only, and are thus not necessarily drawn to scale. Elements common between figures may retain the same numerical designation. While the materials described and illustrated herein may be formed as layers, the materials are not limited thereto and may be formed in other three-dimensional configurations.

As used herein, the singular forms “a,” “an,” and “the” are intended to include the plural forms as well, unless the context clearly indicates otherwise.

As used herein, “and/or” includes any and all combinations of one or more of the associated listed items.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., materials, structures, regions, circuitry, devices) described as “neighboring” one another means and includes features of the disclosed identity (or identities) that are located most proximate (e.g., closest to) one another. Additional features (e.g., additional regions, additional structures, additional regions, additional circuitry, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, the term “about” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “memory device” means and includes microelectronic devices exhibiting memory functionality, but not necessarily limited to memory functionality. Stated another way, and by way of example only, the term “memory device” means and includes not only memory (e.g., volatile memory, such as dynamic random access memory (DRAM); non-volatile memory, such as NAND memory), but also includes an application specific integrated circuit (ASIC) (e.g., a system on a chip (SoC)), an electronic device combining logic and memory, or a graphics processing unit (GPU) incorporating memory.

As used herein, “electronic device” includes, without limitation, a memory device, as well as a semiconductor device which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, “substrate” means and includes a base material or construction upon which additional materials are formed. The substrate may be, for example, a semiconductor substrate, a base semiconductor material on a supporting structure, a metal electrode or a semiconductor substrate having one or more materials, structures or regions formed thereon. The substrate may be a conventional silicon substrate, or other bulk substrate comprising a layer of semiconductive material. As used herein, the term “bulk substrate” means and includes not only silicon wafers, but also silicon-on-insulator (SOI) substrates, such as silicon-on-sapphire (SOS) substrates and silicon-on-glass (SOG) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. The substrate may be doped or undoped. By way of non-limiting example, a substrate may comprise at least one of silicon, silicon dioxide, silicon with native oxide, silicon nitride, a carbon-containing silicon nitride, glass, semiconductor, metal oxide, metal, titanium nitride, carbon-containing titanium nitride, tantalum, tantalum nitride, carbon-containing tantalum nitride, niobium, niobium nitride, carbon-containing niobium nitride, molybdenum, molybdenum nitride, carbon-containing molybdenum nitride, tungsten, tungsten nitride, carbon-containing tungsten nitride, copper, cobalt, nickel, iron, aluminum, and a noble metal.

As used herein, “conductive material” means and includes an electrically conductive material, such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe-and Ni-based alloy, a Co-and Ni-based alloy, an Fe-and Co-based alloy, a Co-and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” or “dielectric material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). As used herein, an “insulative structure” means and includes a structure formed of and including one or more insulative materials. As used herein, an “dielectric structure” means and includes a structure formed of and including one or more dielectric materials.

As used herein, the term “semiconductor material” or “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “selectively removable” means and includes a material that exhibits a greater removal rate responsive to exposure to a given removing (e.g., etching) chemistry and/or process conditions relative to another material exposed to the same removal chemistry and/or process conditions. For example, the material may exhibit a removal rate that is at least about five times greater than the removal rate of another material, such as a removal rate of about ten times greater, about twenty times greater, or about forty times greater than the removal rate of the another material. Removal chemistries and conditions (e.g., etch chemistries and etch conditions) for selectively removing a desired material may be selected by a person of ordinary skill in the art.

As used herein, the term “sacrificial,” when used in reference to a material or structure, means and includes a material, structure, or a portion of a material or structure that is formed during a fabrication process but which is at least partially removed (e.g., substantially removed) prior to completion of the fabrication process.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “work-function” refers to a bulk chemical potential of a material (e.g., metal) relative to the vacuum level.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

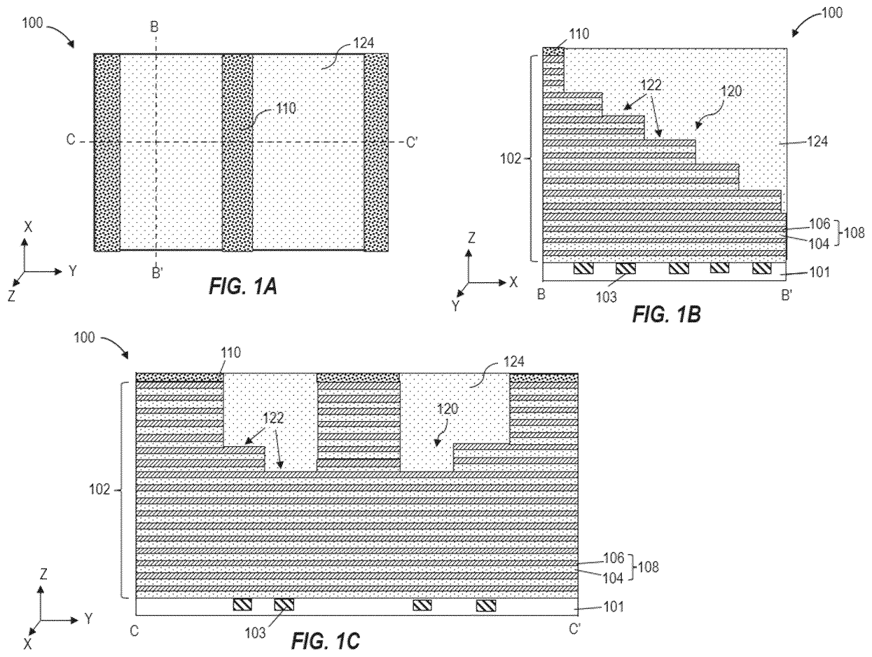

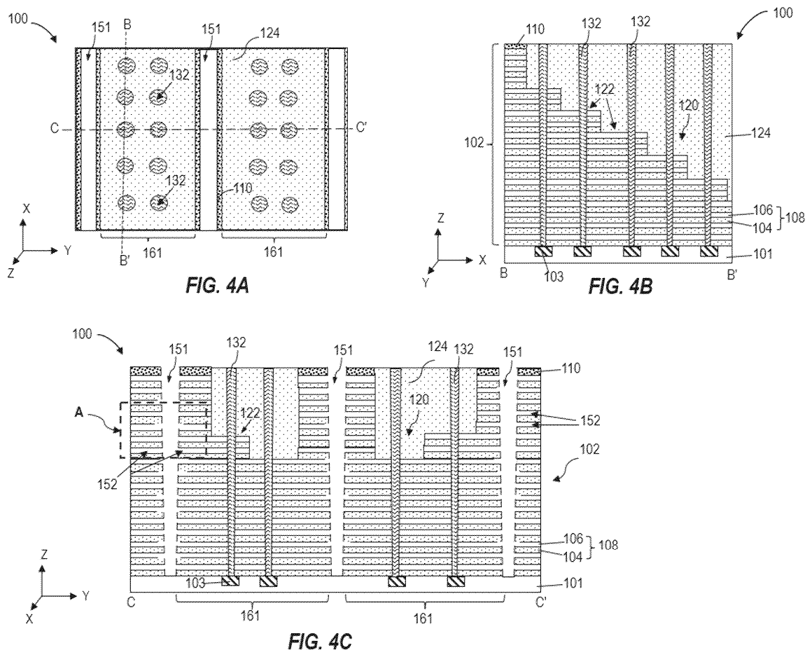

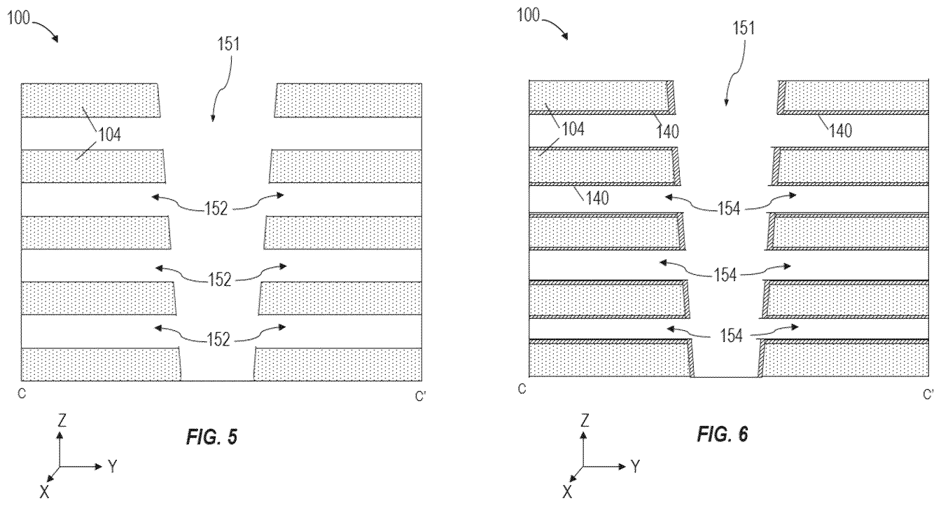

FIG. 1A through FIG. 13C are simplified, partial top-down views (FIGS. 1A, 2A, 3A, 4A and 13A) and simplified, partial cross-sectional views (FIGS. 1B, 1C, 2B, 2C, 3B, 3C, 4B, 4C, 5 through 12, 13B and 13C) of portions of a microelectronic device structure 100 (e.g., a memory device structure) at various processing stages for a method of forming a microelectronic device (e.g., a memory device, such as a 3D NAND Flash memory device), according to some embodiments of the disclosure. As described in further detail below, the method described with reference to FIG. 1A through FIG. 13C may effectuate the formation of a microelectronic device having reduced structural defects (e.g., reduced tier bending or deflection) relative to conventional microelectronic devices. FIG. 5 through FIG. 10 illustrate an enlarged portion of the cross-sectional view of box A of FIG. 4C. With the description provided below, it will be readily apparent to one of ordinary skill in the art that the methods and structures described herein with reference to FIG. 1A through FIG. 13C may be used in the formation and configuration of various devices and electronic systems. In other words, the methods of the disclosure may be used whenever it is desired to form a microelectronic device. For convenience in describing FIG. 1A through FIG. 13C, a first horizontal direction may be defined as the X-direction shown in some of FIG. 1A through FIG. 13C; a second horizontal direction orthogonal (e.g., perpendicular) to the first horizontal direction may be defined as the Y-direction shown in some of FIG. 1A through FIG. 13C; and a vertical direction orthogonal (e.g., perpendicular) to each of the first horizontal direction and the second horizontal direction may be defined as the Z-direction shown in some of FIG. 1A through FIG. 13C.

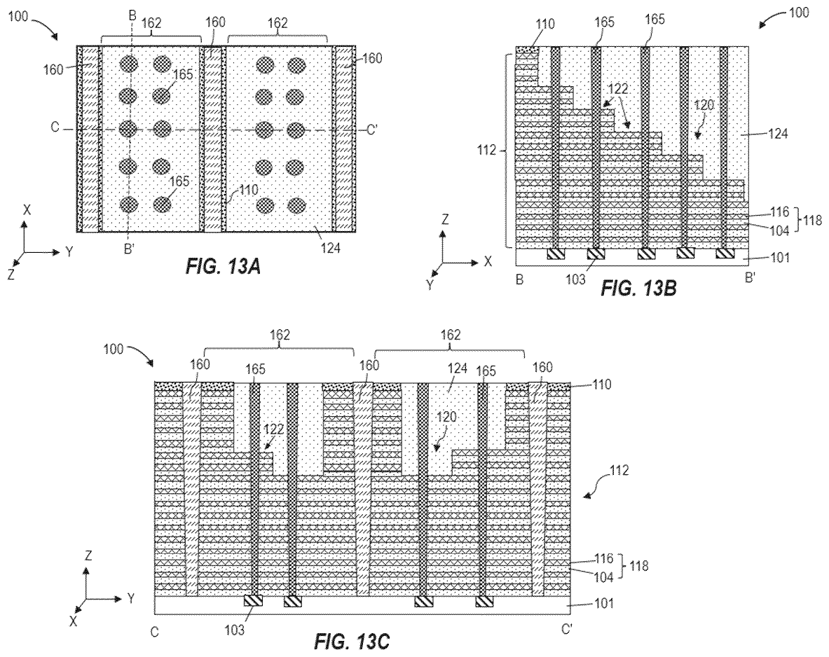

With collective reference to FIGS. 1A through 1C, a microelectronic device structure 100 may be formed to include a preliminary stack structure 102 over a substrate 101. The substrate 101 may, for example, include conductive structures 103 (e.g., conductive routing structures, conductive line structures) to be in electrical communication with conductive contact structures (e.g., the conductive contact structures 165 described below with reference to FIGS. 13A to 13C) that will be formed in later processing stages. The preliminary stack structure 102 is described in further detail below, along with additional components (e.g., structures, features) of the microelectronic device structure 100 at the processing stage depicted in FIGS. 1A through 1C. FIG. 1B is a simplified, partial cross-sectional view of the microelectronic device structure 100 about the dash line B-B′ shown in FIG. 1A; and FIG. 1C is a simplified, partial cross-sectional view of the microelectronic device structure 100 about the dash line C-C′ shown in FIG. 1A. For clarity and ease of understanding of the drawings and related description, not all features depicted in one of FIGS. 1A through 1C are depicted in each of the others of FIGS. 1A through 1C.

The preliminary stack structure 102 may be formed to include a vertically alternating sequence of insulative material 104 and sacrificial material 106 arranged in tiers 108. Each of the tiers 108 may individually include a level of the insulative material 104 vertically neighboring (e.g., adjacent) a level of the sacrificial material 106. Each level (e.g., vertical elevation) of the insulative material 104 and the sacrificial material 106 may respectively have a desired vertical thickness. Each level of the insulative material 104 may have substantially the same vertical thickness as one another, or at least one level of the insulative material 104 may have a different vertical thickness than at least one other level of the insulative material 104. Furthermore, each level of the sacrificial material 106 may have substantially the same vertical thickness as one another, or at least one level of the sacrificial material 106 may have a different thickness than at least one other level of the sacrificial material 106. In some embodiments, the insulative material 104 and the sacrificial material 106 respectively have a vertical thickness within a range of from about 10 nanometers (nm) to about 400 nm. In some embodiments, the insulative material 104 and the sacrificial material 106 respectively have a vertical thickness within a range of from about 10 nm to about 50 nm, such as from about 20 nm to about 50 nm.

The insulative material 104 of the preliminary stack structure 102 may be formed of and include at least one insulative material having different etch selectivity than the sacrificial material 106 of the preliminary stack structure 102. In some embodiments, the insulative material 104 is formed of and includes silicon oxide (e.g., SiO₂). The sacrificial material 106 of the preliminary stack structure 102 may be formed of and include at least one material that can be removed selectively relative to the insulative material 104. As a non-limiting example, the sacrificial material 106 may be removed at etch rate that is at least two times (2×) faster than an etch rate of the insulative material 104 during mutual exposure to an etchant (e.g., a wet etchant). The sacrificial material 106 may, for example, be formed of and include one or more of insulative material, semiconductor material, and conductive material. In some embodiments, the sacrificial material 106 is formed of and includes silicon nitride (e.g., Si₃N₄).

In FIGS. 1B and 1C, the preliminary stack structure 102 is shown as having seventeen (17) tiers 108 of the insulative material 104 vertically alternating with the sacrificial material 106. However, the disclosure is not limited; and fewer or more tiers 108 of the insulative material 104 and the sacrificial material 106 may be included in the preliminary stack structure 102. A quantity of tiers 108 of the insulative material 104 and the sacrificial material 106 may, for example, be within a range from about two (2) to about one-thousand and twenty-four (1024).

Moreover, in some embodiments, the preliminary stack structure 102 is formed to include a dielectric material 110 over an uppermost tier 108 of the preliminary stack structure 102. In some embodiments, the dielectric material 110 has a same material composition as the insulative material 104 of the tiers 108. In some embodiments, the dielectric material is formed of and includes silicon oxide (e.g., SiO₂). In additional embodiments, the dielectric material 110 is not formed over the uppermost tier 108 of the preliminary stack structure 102 at the processing stage of FIGS. 1A through 1C.

The preliminary stack structure 102 may be formed to further include at least one staircase structure 120. Each staircase structure 120 may individually be formed to include steps 122 comprising edges (e.g., horizontal ends) of the tiers 108 of the preliminary stack structure 102. In some embodiments as shown in FIG. 1B and FIG. 1C, two (2) of the tiers 108 of the insulative material 104 and the sacrificial material 106 correspond to one (1) step 122 of the staircase structure 120. Alternatively, in some other embodiments, one (1) tier 108 of the insulative material 104 and the sacrificial material 106 corresponds to one (1) step 122 of the staircase structure 120. In some embodiments, within a given preliminary block area 161, a single step extends across a given vertical elevation in the Y-direction, rather than the skewed (two-step) configuration shown in FIG. 1C. For clarity and ease of understanding the description, FIG. 1B illustrates only a particular quantity of steps 122 in the staircase structure 120. However, it will be understood that the staircase structure 120 may include a greater quantity of steps 122 than those illustrated. For example, the staircase structure 120 may include greater or equal to eight (8) of the steps 122, greater than or equal to sixteen (16) of the steps 122, greater than or equal to thirty-two (32) of the steps 122, greater than or equal to sixty-four (64) of the steps 122, greater than or equal to one-hundred twenty-eight (128) of the steps 122, or greater than or equal to two-hundred fifty-six (256) of the steps 122.

An insulative fill material 124 may be formed to fill at least one valley (e.g., space, gap, trench) vertically overlying and within a horizontal area of the staircase structure 120. The insulative fill material 124 may be formed to laterally intervene between portions of the dielectric material 110, as shown in FIG. 1C. Following formation of the insulative fill material 124, the microelectronic device structure 100 may, optionally, be subjected to a chemical mechanical planarization (CMP) process to remove material (e.g., additional portions of the insulative fill material 124) overlying the preliminary stack structure 102.

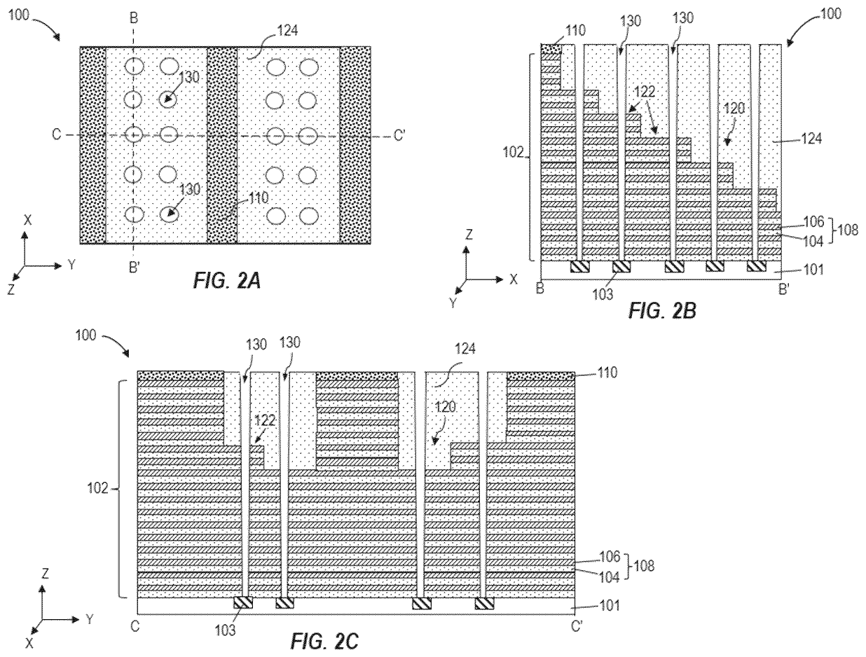

Referring to next FIGS. 2A through 2C, contact openings 130 may be formed to extend vertically from an upper surface of the insulative fill material 124 through an entire vertical extent (e.g., a height) of the preliminary stack structure 102 to or into the conductive structures 103 underlying the preliminary stack structure 102. At least portions of each of the insulative fill material 124, the insulative material 104, and the sacrificial material 106 may be removed by exposing the respective materials to wet etch and/or dry etch chemistries, for example, in one or more material removal processes.

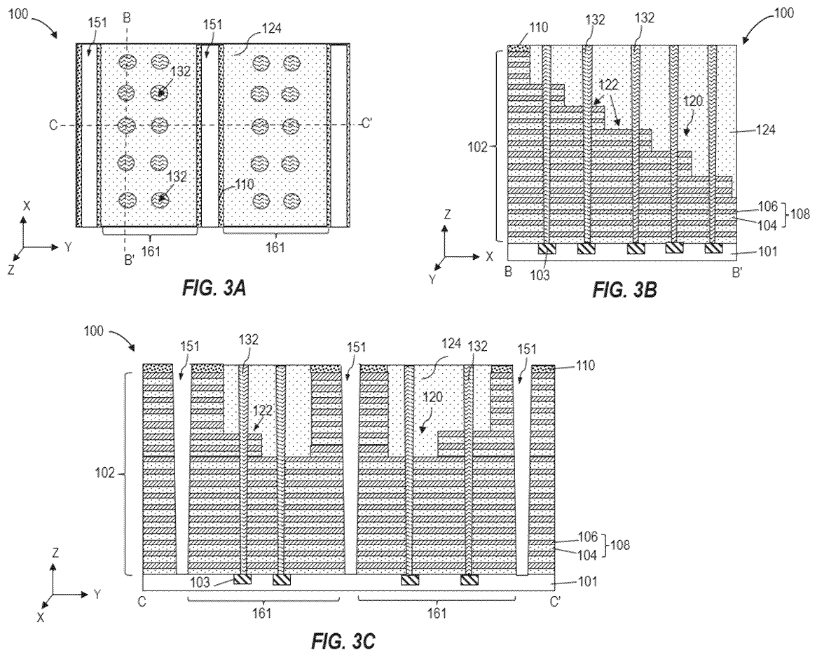

Referring next collectively to FIGS. 3A through 3C, additional sacrificial material may be formed within the contact openings 130 (FIGS. 2A through 2C) to form sacrificially filled contact openings 132. For instance, the additional sacrificial material may be formed within the contact openings 130 through a non-conformal deposition process, such as a spin-on coating process, followed by a planarization process (e.g., a CMP process) to fill (e.g., substantially fill) the contact openings 130 (FIGS. 2A through 2C). The additional sacrificial material may be formed of and include at least one material exhibiting etch selectivity with respect to each of the insulative fill material 124 and the insulative material 104, as well as to additional materials (e.g., additional conductive materials) formed during subsequent processing of the microelectronic device structure 100. In some embodiments, the additional sacrificial material comprises conductive material. By way of non-limiting example, the sacrificial material may be formed of and include one or more of polysilicon, tungsten, titanium, titanium nitride, aluminum oxide, or another material. In some embodiments, the sacrificial material comprises amorphous silicon or polycrystalline silicon. In some such embodiments, the sacrificial material may be doped with one or more dopants, such as with at least one N-type dopant (e.g., one or more of arsenic, phosphorous, antimony, and bismuth) or at least one P-type dopant (e.g., one or more of boron, aluminum, and gallium). In other embodiments, the sacrificial material comprises tungsten. After forming the sacrificially filled contact openings 132, the microelectronic device structure 100 may be exposed to a CMP process to remove the additional sacrificial material outside of boundaries of the contact openings 130.

Slots 151 (also referred to herein as “replacement gate slots”) may also be formed extending vertically through an entire vertical extent (e.g., a height) of the preliminary stack structure 102 to facilitate the replacement of the sacrificial material 106 with conductive material. The slots 151 may horizontally extend in parallel in the X-direction and may horizontally neighbor the sacrificially filled contact openings 132 in the Y-direction. The slots 151 may define preliminary block area 161 for the preliminary stack structure 102. The preliminary block area 161 may horizontally extend in parallel in the X-direction and may horizontally alternate with the slots 151 in the Y-direction. At least portions of each of the dielectric material 110, the insulative material 104, and the sacrificial material 106 may be removed by exposing the respective materials to wet etch and/or dry etch chemistries, for example, in one or more material removal processes. Prior to formation of the slots 151, portions of the insulative fill material 124 and the preliminary stack structure 102 may be covered with an additional dielectric material (e.g., an additional portion of the dielectric material 110) and/or an additional mask material configured and positioned to protect the insulative fill material 124 and the sacrificial material of the sacrificially filled contact openings 132 from being removed (e.g., exhumed) during the material removal processes of the materials of the preliminary stack structure 102.

Referring next to FIGS. 4A through 4C, the microelectronic device structure 100 of FIGS. 3A through 3C may be subjected to a material removal process to selectively remove (e.g., exhumed) the sacrificial material 106 (FIGS. 3B and 3C) of the preliminary stack structure 102 through the slots 151. For example, the microelectronic device structure 100 of FIGS. 3A through 3C may be subjected to a stripping process, such as a wet nitride stripping (WNS) process, to selectively remove the sacrificial material 106 (FIGS. 3B and 3C) relative to the insulative material 104. As a non-limiting example, when the insulative material 104 includes SiO₂ and the sacrificial material 106 (FIGS. 3B and 3C) includes Si₃N₄, the sacrificial material 106 may be selectively removed using phosphoric acid as an etchant.

FIG. 5 through FIG. 8 illustrate an enlarged portion of box A of FIG. 4C at various processing stages for the method of forming a microelectronic device, according to some embodiments of the disclosure.

As shown in FIG. 5, the removal of the sacrificial material 106 (FIG. 3C) may effectuate the formation of first voids 152 vertically alternating with the insulative material 104. The first voids 152 may respectively be at least partially defined by exposed surfaces of remaining portions the insulative material 104 of vertically neighboring tiers 108 (FIGS. 4B and 4C) of the preliminary stack structure 102 (FIGS. 4B and 4C, as modified by the removal of the sacrificial material 106 of the tiers 108). Each of the first voids 152 may be continuous with a respective one of the slots 151.

Referring next to FIG. 6, a dielectric liner 140 may be conformally formed (e.g., substantially continuously formed) on exposed surfaces defining boundaries of the first voids 152 (FIG. 5) and the slots 151, such as on exposed surfaces of remaining portions of the insulative material 104 of the tiers 108 (FIGS. 4B and 4C). The dielectric liner 140 may substantially continuously line and partially fill the first voids 152 (FIG. 5), resulting in second voids 154 having relatively less volume than the first voids 152.

The dielectric liner 140 may be formed of and include dielectric material. In some embodiments, the dielectric liner 140 comprises a high-K dielectric material. As used herein, the term “high-K dielectric material” refers to a material with a higher dielectric constant than SiO₂. Any known high-K dielectric materials may be used for the dielectric liner 140. By way of non-limiting example, the dielectric liner 140 may be formed of and include one or more of hafnium oxide, zirconium oxide, vanadium oxide, titanium oxide, tin oxide, aluminum oxide, zinc oxide, hafnium silicon oxide, and zirconium silicon oxide. In some embodiments, the dielectric liner 140 is formed of and includes aluminum oxide. In some embodiments, the dielectric liner 140 has a thickness within a range of from about 1 nm to about 5 nm.

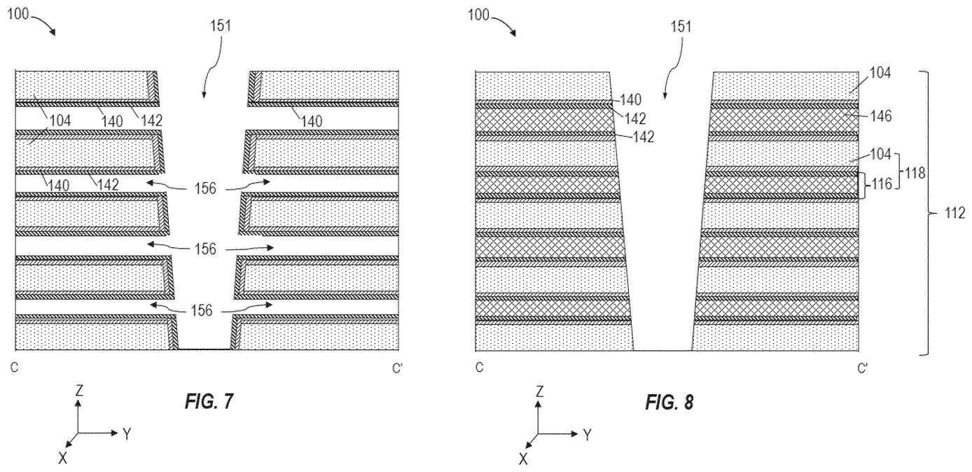

Referring next to FIG. 7, an amorphous alloy liner 142 may be conformally formed (e.g., substantially continuously formed) on or over the dielectric liner 140. The amorphous alloy liner 142 may be formed to substantially extend (e.g., horizontally extend and vertically extend) over and cover portions of the dielectric liner 140 defining the second voids 154 (FIG. 6) and remaining portions of the slots 151. The amorphous alloy liner 142 may partially (e.g., less than completely) fill the second voids 154 (FIG. 6) defined by the dielectric liner 140, resulting in third voids 156 having relatively less volume than the second voids 154 (FIG. 6). A thickness of the amorphous alloy liner 142 may be within a range of from about 0.25 nm to about 10 nm, such as from about 0.5 nm to about 7.5 nm, from about 0.5 nm to about 5 nm, from about 0.5 nm to about 2.5 nm, from about 1 nm to about 5 nm, or from about 1 nm to about 2 nm. In some embodiments, a thickness of the amorphous alloy liner 142 is within a range of from about 1 nm to about 2 nm. In some embodiments, a thickness of the amorphous alloy liner 142 is within a range of from about 0.5 nm to about 2.5 nm.

The amorphous alloy liner 142 may be formed of and include a doped conductive material. The doped conductive material of the amorphous alloy liner 142 may include a first conductive material and a dopant distributed within the first conductive material.

The first conductive material of the amorphous alloy liner 142 may be formed of and include an elemental metal (e.g., molybdenum, tungsten, titanium, cobalt, nickel, platinum, ruthenium, copper), a conductive metal-containing material (e.g., metal nitride, metal silicide, metal carbide), a conductively-doped-semiconductor material (e.g., silicon, gallium), or a combination thereof. For example, the first conductive material may be formed of and include one or more of copper (Cu), cobalt (Co), tungsten (W), aluminum (Al), ruthenium (Ru), iridium (Ir), molybdenum (Mo), platinum (Pt), tantalum (Ta), titanium (Ti), and rhodium (Rh). In some embodiments, the first conductive material of the amorphous alloy liner 142 is formed of and includes molybdenum (Mo).

The dopant of the amorphous alloy liner 142 may include one or more of boron (B), carbon (C), silicon (Si), at least one compound including one or more thereof, or a combination thereof. In some embodiments, the amorphous alloy liner 142 includes a Mo-containing material (e.g., elemental Mo, a Mo-containing alloy) doped with one or more of B, C, and Si. The dopant included within the amorphous alloy liner 142 may be provided from a precursor compound utilized during the formation of the amorphous alloy liner 142. As non-limiting examples, precursor compounds for boron dopant within the amorphous alloy liner 142 include diborane (B₂H₆) and boron trifluoride (BF₃). As non-limiting additional examples, precursor compounds for carbon dopant within the amorphous alloy liner 142 include hydrocarbons such as methane (CH₄) and ethane (C₂H₆). As non-limiting further examples, precursor compounds for silicon dopant within the amorphous alloy liner 142 include silane (SiH₄) and disilane (Si₂H₆).

The dopant may be present in the doped conductive material of the amorphous alloy liner 142 at an amount sufficient to render the doped conductive material in an amorphous phase. As used herein, the term “amorphous” means and refers to a material having a substantially non-crystalline structure. In some embodiments, the amorphous alloy liner 142 is formed of and includes a doped molybdenum having a thickness within a range of from about 1 nm to about 2 nm, and the dopant (e.g., boron, carbon, silicon) is present in the amorphous alloy liner 142 in amount sufficient to render such alloy liner 142 in the amorphous phase. In some embodiments, the amorphous alloy liner 142 is formed of and includes a doped conductive metal (e.g., a doped molybdenum), and an amount of the dopant within the amorphous alloy liner 142 is within a range of from about 20 atomic % to about 50 atomic %. The amorphous alloy liner 142 may be substantially homogeneous in composition, with the dopant distributed substantially uniformly therein. Alternatively, the amorphous alloy liner 142 may be heterogeneous in composition (e.g., have a gradient change in the composition, have a step-wise change in the composition) with a higher concentration of dopant in one region thereof relative to at least one other region thereof.

The amount of dopant (e.g., boron, carbon, silicon) in the doped conductive material of the amorphous alloy liner 142 may be adjusted to provide different templates for growth of a second conductive material (e.g., the second conductive material 146 described below with reference to FIGS. 8 and 10) to be formed on or over the amorphous alloy liner 142 in later process stages, to obtain stress control and good nucleation during the formation of the second conductive material. Moreover, when the dopant of the doped conductive material (e.g., Si-doped molybdenum, Si-doped molybdenum-containing material) includes Si, the Si dopant may impart the microelectronic device structure 100 with relatively enhanced structural strength during the replacement gate process (e.g., to mitigate undesirable tier collapse).

In some embodiments, the first conductive material (e.g., molybdenum-containing material, metal) is formed (e.g., substantially continuously formed) on or over the dielectric liner 140, and then one or more dopants are incorporated into the first conductive material to form the amorphous alloy liner 142. In some embodiments, an organometallic precursor containing at least one dopant therein is formed (e.g., substantially continuously formed) on or over the dielectric liner 140, and then the doped organometallic precursor is converted to the amorphous alloy liner 142.

Referring next to FIG. 8, a stack structure 112 may be formed by substantially filling the third voids 156 (FIG. 7) defined by the amorphous alloy liner 142 with a second conductive material 146. The stack structure 112 includes tiers 118 respectively including a level of composite conductive material 116 vertically neighboring a level of insulative material 104. The composite conductive material 116 of an individual tier 118 may include the second conductive material 146 and the amorphous alloy liner 142 substantially covering upper and lower surfaces of the second conductive material 146. For an individual level of the composite conductive material 116, the amorphous alloy liner 142 of the composite conductive material 116 may be interposed between the second conductive material 146 of the composite conductive material 116 and the level of insulative material 104 of the tier 118. In addition, for an individual tier 118, the dielectric liner 140 may at least cover upper and lower surfaces of the insulative material 104 of the level of insulative material 104 of the tier 118. The dielectric liner 140 may be vertically interposed between the composite conductive material 116 of the tier 118 and the insulative material 104 of the tier 118.

The second conductive material 146 may be substantially the same as or different than the first conductive material of the amorphous alloy liner 142. In some embodiments, the second conductive material 146 is an undoped conductive material. In some embodiments, the second conductive material 146 is formed of a single (e.g., only one) material (e.g., only one elemental metal, only one single metal-containing material). In some other embodiments, the second conductive material 146 comprises multiple materials (e.g., multiple elemental metals, multiple metal-containing materials). The second conductive material 146 may be substantially homogeneous or may be heterogeneous. In some embodiments, the second conductive material 146 has a relatively lower work function than that of the amorphous alloy liner 142. In additional embodiments, the second conductive material 146 has a relatively higher work function than that of the amorphous alloy liner 142. In further embodiments, the second conductive material 146 has substantially the same work function as that of the amorphous alloy liner 142.

In some embodiments, the amorphous alloy liner 142 comprises a doped conductive metal, and the second conductive material 146 comprises an undoped conductive metal. In some embodiments, the amorphous alloy liner 142 comprises a first conductive metal and a dopant distributed within the first conductive metal, and the second conductive material 146 comprises a second conductive metal. In some of such embodiments, a material composition of the first conductive metal is the same as that of the second conductive metal. In additional embodiments, a material composition of the first conductive metal of the amorphous alloy liner 142 is different than that of the second conductive material 146.

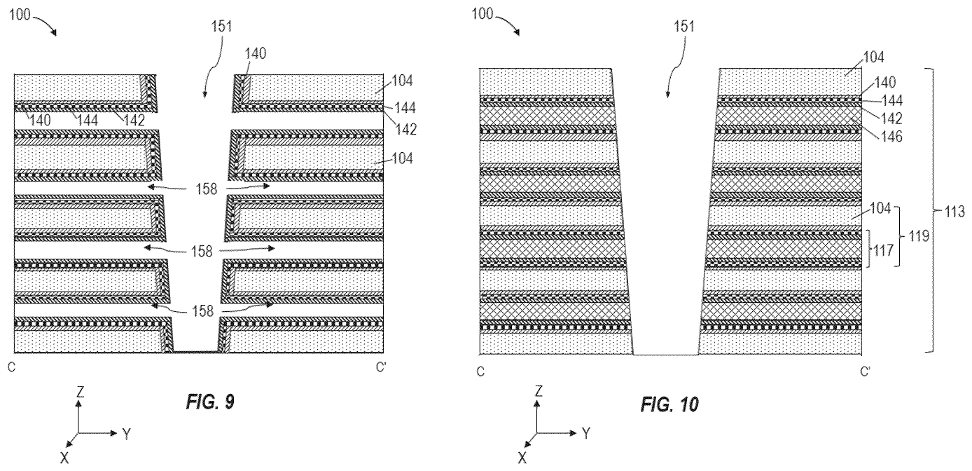

FIGS. 9 and 10 illustrate an enlarged portion of box A of FIG. 4C at various processing stages for a method of forming a microelectronic device, according to some additional embodiments of the disclosure. The processing stage of FIG. 9 may occur after the processing stage previously described with reference to FIG. 6, and the processing stage of FIG. 10 may occur after the processing stage of FIG. 9. Put another way, the processing stage of FIG. 9 may be effectuated instead of the processing stage previously described with reference to FIG. 7, and the processing stage of FIG. 10 may be effectuated instead of the processing stage previously described with reference to FIG. 8.

Referring to FIG. 9, a metal nitride liner 144 may be conformally formed on or over the dielectric liner 140 within the third voids 156 (FIG. 6) and the slots 151, and the amorphous alloy liner 142 may be conformally formed (e.g., substantially continuously formed) on or over the metal nitride liner 144. The metal nitride liner 144 and the amorphous alloy liner 142 may partially (e.g., less than completely) fill remaining portions of the third voids 156 (FIG. 6) unoccupied by the dielectric liner 140, resulting in fourth voids 158 having relatively less volume than the third voids 156.

The metal nitride liner 144 may be formed of and include a metal nitride material. In some embodiments, the metal nitride liner 144 is formed of and includes a ternary metal nitride compound. As used herein, a “ternary metal nitride compound” means and includes a metal nitride formed of three elements—namely, nitrogen element, metal element, and one additional element that may be metallic element or non-metallic element. Non-limiting examples of the ternary metal nitride compounds include titanium silicon nitride (TiSiN), titanium aluminum nitride (TiAlN), titanium chromium nitride (TiZrN), titanium zirconium nitride (TiCrN). In some embodiments, the ternary metal nitride compound includes titanium silicon nitride (TiSiN), titanium aluminum nitride (TiAlN), or a combination thereof. The ternary metal nitride compound may be formed by any method known in the art, such as physical vapor deposition (PVD), magnetron sputtering, ion bean assisted deposition, chemical vapor deposition (CVD), plasma assist CVD.

Referring next to FIG. 10, a stack structure 113 may be formed by substantially filling the fourth voids 158 (FIG. 9) defined by the amorphous alloy liner 142 with the second conductive material 146. The stack structure 113 comprises tiers 119 respectively including a level of composite conductive material 117 vertically neighboring a level of insulative material 104. The composite conductive material 117 of an individual tier 119 may include the second conductive material 146; the amorphous alloy liner 142 substantially covering upper and lower surfaces of the second conductive material 146; and the metal nitride liner 144 substantially covering upper and lower surfaces of the amorphous alloy liner 142. For an individual level of the composite conductive material 117, the amorphous alloy liner 142 of the composite conductive material 116 may be interposed between the metal nitride liner 144 of the composite conductive material 117 and the level of insulative material 104 of the tier 119. In addition, for an individual tier 119, the dielectric liner 140 may at least cover upper and lower surfaces of the insulative material 104 of the level of insulative material 104 of the tier 119. The dielectric liner 140 may be vertically interposed between the composite conductive material 117 of the tier 119 and the insulative material 104 of the tier 119.

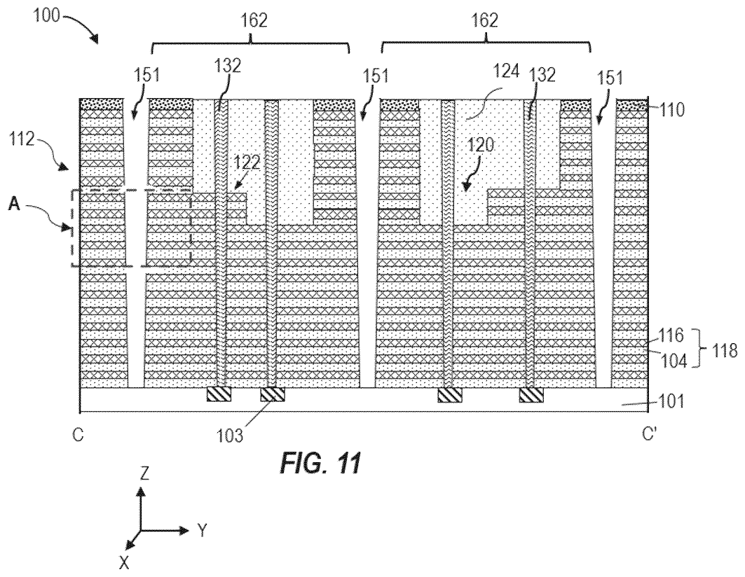

FIG. 11 illustrates the microelectronic device structure 100 of FIG. 4C either after lining the first voids 152 (FIG. 4C) with the dielectric liner 140 and the amorphous alloy liner 142, and filling the third voids 156 (FIG. 7) with the second conductive material 146 as described with reference to FIGS. 5 through 8, or after lining the first voids 152 (FIG. 4C) with the dielectric liner 140, the metal nitride liner 144 and the amorphous alloy liner 142, and filling the fourth voids 158 (FIG. 9) with the second conductive material 146 as described with reference to FIGS. 5, 6, 9 and 10. Thus, in some embodiments, the enlarged portion of box A of FIG. 11 may be as shown in FIG. 8; and in additional embodiments, the enlarged portion of box A of FIG. 11 may be as shown in FIG. 10.

As shown in FIG. 11, the microelectronic device structure 100 includes a stack structure 112 (or the stack structure 113 (FIG. 10)) comprising a vertical alternating sequence of the insulative material 104 and composite conductive material 116 (or the composite conductive material 117 (FIG. 10)) arranged in the tiers 118 (or the tiers 119 (FIG. 10)). At least one vertically (e.g., in the Z-direction) lower composite conductive material 116 of the stack structure 112 may be employed as at least one lower select gate (e.g., at least one source side select gate (SGS)) of the microelectronic device structure 100. In some embodiments, a single (e.g., only one) composite conductive material 116 of a vertically lowermost tier 118 of the stack structure 112 is employed as a lower select gate (e.g., a SGS) of the microelectronic device structure 100. In addition, vertically (e.g., in the Z-direction) upper composite conductive material(s) 116 of the stack structure 112 may be employed as upper select gate(s) (e.g., drain side select gate(s) (SGDs)) of the microelectronic device structure 100. In some embodiments, horizontally neighboring composite conductive material 116 of a vertically uppermost tier 118 of the stack structure 112 (e.g., separated from each other by slots) are employed as upper select gates (e.g., SGDs) of the microelectronic device structure 100. In some embodiments, more than one (e.g., two, four, five, six) composite conductive material 116 are employed as upper select gates (e.g., SGDs) of the microelectronic device structure 100.

The microelectronic device structure 100 also includes staircase structure(s) 120 comprising steps 122 defined by the edges (e.g., horizontal ends) of the tiers 118 (or the tiers 119 (FIG. 10)). The sacrificially filled contact openings 132 extend vertically through an entire vertical height of the stack structure 112 (or the stack structure 113 (FIG. 10)). The slots 151 extend vertically through an entire vertical height of the stack structure 112 (or the stack structure 113 (FIG. 10)). The slots 151 may horizontally extend in parallel in the X-direction and may horizontally neighbor the sacrificially filled contact openings 132 in the Y-direction. The slots 151 may define blocks 162 for the stack structure 112. The blocks 162 may horizontally extend in parallel in the X-direction and may horizontally alternate with the slots 151 in the Y-direction.

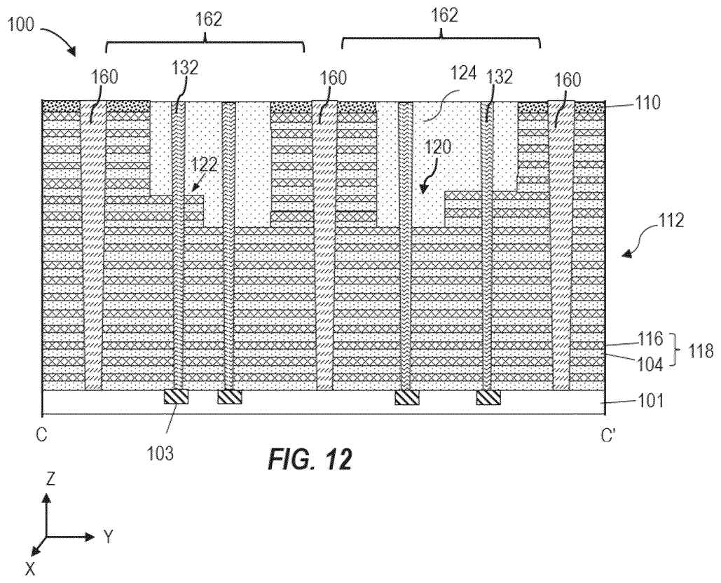

Referring to FIG. 12, block isolation structures 160 may be formed within the slots 151 (FIG. 11). The block isolation structures 160 extend vertically through an entire vertical height of the stack structure 112 (or the stack structure 113 (FIG. 10)). The block isolation structures 160 may be formed of and include an insulative material, such as dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), dielectric nitride material (e.g., SiN_{y}), dielectric oxynitride material (e.g., SiOₓN_{y}), and dielectric carboxynitride material (e.g., SiOₓC_{z}N_{y}). A material composition of the block isolation structures 160 may be substantially the same as a material composition of dielectric material 110 and the insulative material 104 of the stack structure 155, or the material composition of the block isolation structures 160 may be different than the material composition of the dielectric material 110 and/or the insulative material 104. In some embodiments, the block isolation structures 160 are respectively formed of and include silicon dioxide. In additional embodiments, the block isolation structures 160 are respectively formed of and include a first material (e.g., semiconductor material, conductive material) surrounded by (e.g., lined with) insulative material. The insulative material may be interposed between the first material and the stack structure 112. After forming the block isolation structures 160, the microelectronic device structure 100 may be exposed to a chemical mechanical planarization (CMP) process to remove the dielectric material outside of boundaries of the slots 151 (FIG. 11). The block isolation structures 160 extend horizontally in parallel with one another in the X-direction.

Referring next collectively to FIGS. 13A through 13C, the sacrificial material of the sacrificially filled contact openings 132 may be selectively removed to form contact openings, which are then filled (e.g., substantially filled) with insulative material, or a combination of insulative material and one or more of conductive material and semiconductor material to form contact structures 165. Each of the contact structures 165 (FIGS. 13B and 13C) may extend vertically from the upper surface of the insulative fill 124, through an entire vertical height of the stack structure 112, and to the conductive structures 103 underlying the stack structure 112. The contact structures 165 may respectively be employed as one or more of support structures and active structures (e.g., structures facilitating desired conductive paths through the stack structure 112 during use and operation of a microelectronic device including the microelectronic device structure 100).

FIG. 13A depicts each of the contact structures 165 as having a substantially circular horizontal cross-sectional shape. However, the disclosure is not limited, and additional configurations of the contact structures 165 may be contemplated. For example, one or more of the contact structures 165 may individually exhibit a generally ovular horizontal cross-sectional shape, a generally elliptical horizontal cross-sectional shape, a generally rectangular horizontal cross-sectional shape, or a generally square horizontal cross-sectional shape. Furthermore, the contact structures 165 are depicted as being arranged into rows respectively including a group of the contact structures 165 substantially aligned with each in the X-direction. However, the disclosure is not limited, and at least one of the contact structures 165 may be horizontally offset relative to one another in any way desired.

The amorphous alloy liner 142 may serve as support structures during and/or after the formation of one or more components of the microelectronic device structure 100. For example, the amorphous alloy liner 142 may serve as support structures for the formation of the composite conductive material 116 (or the composite conductive material 117 (FIG. 10)) during replacement of the sacrificial material 106 (FIGS. 4A through 11) to form the stack structure 112 (or the stack structure 113 (FIG. 10)). The amorphous alloy liner 142 (FIG. 8) (and the metal nitride liner 144 (FIG. 10), if present) may impede (e.g., prevent) tier bending and/or tier deflection during the selective removal of the sacrificial material 106, compared to conventional device structures without the amorphous alloy liner interposed between the insulative material 104 and the composite conductive material 116 of the stack structure 112. Further, formation of the amorphous alloy liner 142 (and the metal nitride liner 144, if present) prior to performing replacement gate process may provide increased structural support within the staircase structure 120, without undesirably increasing the horizontal footprint of the microelectronic device structure 100.

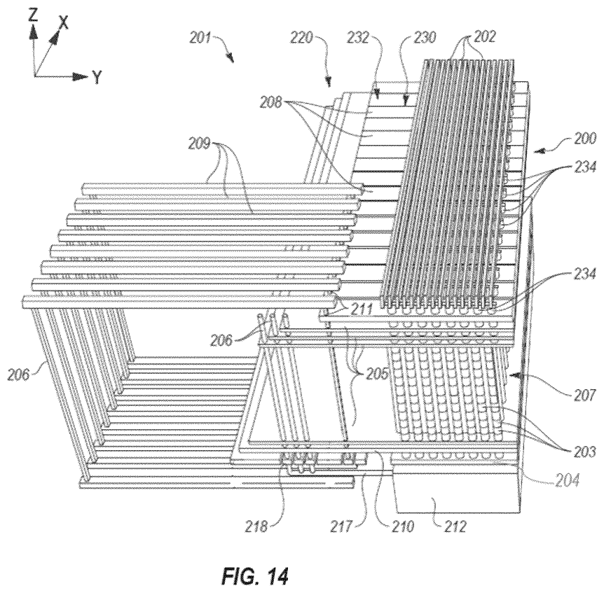

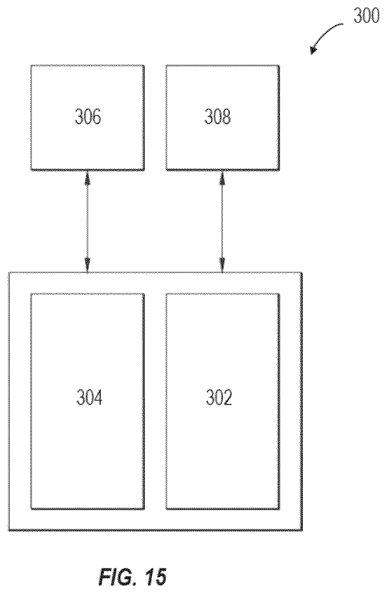

FIG. 14 illustrates a simplified, partial cutaway perspective view of a portion of a microelectronic device 201 (e.g., a memory device, such as a dual deck 3D NAND Flash memory device) including a microelectronic device structure 200. The microelectronic device structure 200 may be substantially similar to the microelectronic device structure 100 following the processing stage previously described with reference to FIGS. 13A through 13C.

As shown in FIG. 14, the microelectronic device structure 200 may include a staircase structure 220 (e.g., including the staircase structure 120 (FIGS. 13B and 13C)) defining contact regions for connecting conductive contacts 211 with composite conductive material (e.g., corresponding to the composite conductive material 116 (FIG. 8) or the composite conductive material 117 (FIG. 10)) of tiers 205 (e.g., corresponding to the tiers 118 (FIG. 8) or the tiers 119 (FIG. 10)). The composite conductive material of some of the tiers 205 may be employed as local word line (LWL) structures of the microelectronic device 201; and the composite conductive material of some others of the tiers 205 may be employed as first select gates 208 (e.g., upper select gates, drain select gates (SGDs)) and second select gates 210 (e.g., a lower select gates, a source select gates (SGSs)) of the microelectronic device 201. In addition, the microelectronic device structure 200 may include contact structures 206 (e.g., corresponding to the conductive contact structures 165 (FIGS. 13B and 13C)) within a horizontal area of the staircase structure 220, and vertically extending completely through the tiers 205.

The microelectronic device structure 200 may further include vertically extending strings 207 of memory cells 203 that are coupled to each other in series. The memory cells 203 may be defined by intersections of cell pillar structures and the conductive material 205 (e.g., corresponding to the composite conductive material 116 (FIG. 8) or the composite conductive material 117 (FIG. 10)) of tiers (e.g., corresponding to the tiers 118 (FIG. 8) or the tiers 119 (FIG. 10)) of tiers of a stack structure (e.g., corresponding to the stack structure 112 (FIG. 8), FIG. 10)). The vertically extending strings 207 of memory cells 203 may extend vertically (e.g., in the Z-direction) and orthogonally to data lines 202, a source structure 204, first select gates 208 (e.g., upper select gates, drain select gates (SGDs)), select lines 209, and a second select gate 210 (e.g., a lower select gate, a source select gate (SGS)). The conductive material 205 may extend in respective horizontal planes. The conductive material 205 may be stacked vertically, such that each conductive material 205 is coupled to at least some of the vertical strings 207 of memory cells 203, and the vertical strings 207 of the memory cells 203 extend vertically through the stack structure including the conductive material 205. The conductive material 205 may be coupled to or may form control gates of the memory cells 203.

The microelectronic device structure 200 may further include conductive routing structures 209 coupled to the conductive contacts 211. The conductive contacts 211 may, optionally, electrically couple components to each other as shown. For example, the select lines 209 may be electrically coupled to the first select gates 208 by way of the conductive contacts 211. The microelectronic device 201 may also include multiple blocks 232 (e.g., corresponding to the blocks 162 (FIGS. 13A and 13C)) horizontally separated (e.g., in the Y-direction) from one another by filled slot structures 230 (e.g., corresponding to the block isolation structures 160 (FIGS. 13A and 13C)).

The microelectronic device 201 may also include a control unit 212 positioned under and within a horizontal area of the memory array including the vertically extending strings 207 of memory cells 203. The control unit 212 may include control logic devices configured to control various operations of other features (e.g., the vertically extending strings 207 of memory cells 203) of the microelectronic device 201. By way of non-limiting example, the control unit 212 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control unit 212 may be coupled to the data lines 202, the source structure 204, the conductive routing structures 209, the conductive contacts 211, and the composite conductive material of at least some tiers 205, for example. In some embodiments, the control unit 212 includes CMOS (complementary metal-oxide-semiconductor) circuitry. In such embodiments, the control unit 212 may be characterized as having a “CMOS under Array” (“CuA”) configuration, wherein the CMOS circuitry of a logic region is at least partially (e.g., substantially) positioned within horizontal areas of memory array regions of a microelectronic device including the microelectronic device structure 200.

The first select gates 208 may extend horizontally in a first direction (e.g., the X-direction) and may be coupled to respective first groups of vertical strings 207 of memory cells 203 at a first end (e.g., an upper end) of the vertical strings 207. The second select gate 210 may be coupled to the vertical strings 207 at a second, opposite end (e.g., a lower end) of the vertical strings 207 of memory cells 203. The data lines 202 (e.g., digit lines, bit lines) may extend horizontally in a second direction (e.g., in the Y-direction) that is at an angle (e.g., perpendicular) to the first direction in which the first select gates 208 extend. The data lines 202 may be electrically coupled to the vertical strings 207 through conductive contact structures 234. Individual data lines 202 may be coupled to individual groups of the vertical strings 207 extending the second direction (e.g., the Y-direction) at the first end (e.g., the upper end) of the vertical strings 207 of the individual groups. Additional individual groups of the vertical strings 207 extending the first direction (e.g., the X-direction) and coupled to individual first select gates 208 may share a particular vertical string 207 thereof with individual group of vertical strings 207 coupled to an individual data line 202. Thus, an individual vertical string 207 of memory cells 203 may be selected at an intersection of an individual first select gate 208 and an individual data line 202. Accordingly, the first select gates 208 may be used for selecting memory cells 203 of the vertical strings 207 of memory cells 203.

The first select gates 208 and the second select gates 210 may operate to select a vertical string 207 of the memory cells 203 interposed between data lines 202 and the source structure 204. Thus, an individual memory cell 203 may be selected and electrically coupled to a data line 202 by operation of (e.g., by selecting) the appropriate first select gate 208, second select gate 210, and conductive material 205 that are coupled to the particular memory cell 203.

Conductive structures 218 (e.g., corresponding to the conductive structures 103 (FIGS. 13B and 13C)) may vertically overlap the source structure 204, and may be electrically isolated from one another. Optionally, additional conductive routing structures 217 may be coupled to at least some of the conductive structures 218 and one or more other features of the microelectronic device 201 (e.g., circuitry of the control unit 212).

Thus, in accordance with some embodiments of the disclosure, a microelectronic device comprises a stack structure comprising tiers vertically stacked relative to one another. Each of the tiers comprises a composite conductive material and an insulative material vertically neighboring the composite conductive material. The composite conductive material comprises a conductive material and an amorphous alloy liner on each of an upper surface and a lower surface of the conductive material. The amorphous alloy liner comprises additional conductive material and dopant distributed within the additional conductive material. The dopant comprises or more of boron, carbon, and silicon.

Moreover, in accordance with some embodiments of the disclosure, a memory device comprises a stack structure comprising levels of composite conductive material vertically interleaved with levels of the insulative material. The levels of composite conductive material respectively comprise conductive material and amorphous conductive material substantially covering each of an upper surface of the conductive material and a lower surface of the conductive material. The amorphous conductive material comprises a molybdenum-containing material doped with one or more of boron, carbon, and silicon. The memory device also comprises strings of memory cells vertically extending through the stack structure.

Furthermore, in accordance with some embodiments of the disclosure, a method of forming a microelectronic device includes forming a preliminary stack structure comprising a vertically alternating sequence of insulative material and sacrificial material arranged in tiers. The method also includes forming slots extending vertically through an entire vertical height of the preliminary stack structure. The method further includes replacing the sacrificial material of respective ones of the tiers of the preliminary stack structure with composite conductive material by way of the slots. The composite conductive material comprises an amorphous molybdenum-containing material and a conductive material directly vertically adjacent to the amorphous molybdenum-containing material.

FIG. 15 is a block diagram of an electronic system 300, in accordance with embodiments of the disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 300 includes at least one memory device 302. The memory device 302 may include, for example, an embodiment one or more of a microelectronic device structure (e.g., the microelectronic device structure 100 (FIGS. 13A-13C)) and a microelectronic device (e.g., the microelectronic device 201 (FIG. 14)) of the disclosure.

The electronic system 300 may further include at least one electronic signal processor device 304 (often referred to as a “microprocessor”). The electronic signal processor device 304 may, optionally, include an embodiment of one or more of a microelectronic device structure (e.g., the microelectronic device structure 100 (FIGS. 13A-13C)) and a microelectronic device (e.g., the microelectronic device 201 (FIG. 14)) of the disclosure. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device, comprising:
a stack structure comprising tiers vertically stacked relative to one another and respectively including:
a composite conductive material comprising:
a conductive material; and
an amorphous alloy liner on each of an upper surface and a lower surface of the conductive material, the amorphous alloy liner comprising:
additional conductive material; and
dopant distributed within the additional conductive material and comprising one or more of boron, carbon, and silicon; and
an insulative material vertically neighboring the composite conductive material.

2. The microelectronic device of claim 1, wherein the additional conductive material of the amorphous alloy liner of the composite conductive material comprises a metal.

3. The microelectronic device of claim 1, wherein the additional conductive material of the amorphous alloy liner of the composite conductive material comprises one or more of elemental molybdenum and a molybdenum-containing conductive material.

4. The microelectronic device of claim 1, wherein, for the composite conductive material of respective ones of the tiers, the conductive material and the additional conductive material of the amorphous alloy liner have substantially the same material composition as one another.

5. The microelectronic device of claim 4, wherein, for the composite conductive material of the respective ones of the tiers, the conductive material and the additional conductive material of the amorphous alloy liner each comprise molybdenum.

6. The microelectronic device of claim 1, wherein the tiers of the stack structure respectively further comprise a high-K dielectric material vertically interposed between the insulative material and the amorphous alloy liner of the composite conductive material.

7. The microelectronic device of claim 1, wherein the composite conductive material of respective ones of the tiers further comprises a metal nitride liner on the amorphous alloy liner.

8. The microelectronic device of claim 1, wherein, for the composite conductive material of the respective ones of the tiers, the amorphous alloy liner thereof substantially completely covers each of the upper surface and the lower surface of the conductive material thereof.

9. A memory device, comprising:
a stack structure comprising levels of composite conductive material vertically interleaved with levels of insulative material, the levels of composite conductive material respectively comprising:
conductive material; and
amorphous conductive material substantially covering each of an upper surface of the conductive material and a lower surface of the conductive material, the amorphous conductive material comprising a molybdenum-containing material doped with one or more of boron, carbon, and silicon; and
strings of memory cells vertically extending through the stack structure.

10. The memory device of claim 9, wherein, for respective ones of the levels of composite conductive material of the stack structure, an amount of the one or more of boron, carbon, and silicon within the amorphous conductive material is within a range of from about 20 atomic % to about 50 atomic %.

11. The memory device of claim 9, further comprising:
a staircase structure within the stack structure and having steps comprising horizontal ends of at least some of the levels of composite conductive material; and
conductive contact structures within a horizontal area of the staircase structure and respectively vertically extending completely through the stack structure.

12. The memory device of claim 9, wherein the levels of composite conductive material respectively further comprise metal nitride material vertically interposed between the amorphous conductive material thereof and two of the levels of the insulative material.

13. The memory device of claim 12, wherein the metal nitride material comprises at least one ternary metal nitride compound.

14. The memory device of claim 13, wherein the at least one ternary metal nitride compound comprises one or more of titanium silicon nitride and titanium aluminum nitride.

15. The memory device of claim 9, wherein, for respective ones of the levels of composite conductive material of the stack structure, the conductive material thereof comprises additional molybdenum-containing material substantially undoped with any of the one or more of boron, carbon, and silicon.

16. The memory device of claim 9, wherein, for respective ones of the levels of composite conductive material of the stack structure, the conductive material comprises tungsten.

17. A method of forming a microelectronic device, the method comprising:
forming a preliminary stack structure comprising a vertically alternating sequence of insulative material and sacrificial material arranged in tiers;
forming slots extending vertically through an entire vertical height of the preliminary stack structure;
replacing the sacrificial material of respective ones of the tiers of the preliminary stack structure with composite conductive material by way of the slots, the composite conductive material comprising:
an amorphous molybdenum-containing material; and
a conductive material directly vertically adjacent to the amorphous molybdenum-containing material.

18. The method of claim 17, further comprising forming the amorphous molybdenum-containing material of the composite conductive material to comprise a molybdenum alloy doped with one or more of boron, carbon, and silicon.

19. The method of claim 17, wherein replacing sacrificial material of respective ones of the tiers of the preliminary stack structure with composite conductive material by way of the slots comprises:
removing the sacrificial material of the respective ones of the tiers through the slots to effectuate a formation of voids vertically alternating with the insulative material of the preliminary stack structure;
conformally forming a high-K dielectric material within the voids;
conformally forming the amorphous molybdenum-containing material over inner surfaces of the high-K dielectric material within the voids; and
forming the conductive material on exposed surfaces of the amorphous molybdenum-containing material within the voids.

20. The method of claim 19, wherein replacing sacrificial material of respective ones of the tiers of the preliminary stack structure with composite conductive material by way of the slots further comprises conformally forming a ternary metal nitride material on the inner surfaces of the high-K dielectric material within the voids before conformally forming the amorphous molybdenum-containing material.
